(19) United States
(12) Patent Application Publication
(10) Pub. No.: US 2019/0361062 A1
(43) Pub. Date: Nov. 28, 2019

(54) ELECTROMAGNETIC FIELD PROBE

(71) Applicant: Mitsubishi Electric Corporation, Tokyo (JP)

(72) Inventors: Yusuke YAMAKAJI, Tokyo (JP); Hideyuki OHASHI, Tokyo (JP); Chiharu MIYAZAKI, Tokyo (JP)

(73) Assignee: Mitsubishi Electric Corporation, Tokyo (JP)

(21) Appl. No.: 16/485,521

(22) PCT Filed: Mar. 27, 2017
(86) PCT No.: PCT/JP2017/012363

§ 371 Date: Aug. 13, 2019

(51) Int. Cl. G01R 29/08; G01R 29/12

(52) U.S. Cl. CPC G01R 29/0878; G01R 33/02; G01R 29/0871; G01R 29/12

(57) ABSTRACT

A looped conductor (1) is opened at both ends, one end (1a) is connected to a conductor plate (2), and the other end (1b) is connected to a lead wire (5b). The conductor plate (2) is disposed parallel to a loop surface of the looped conductor (1) and has a shape covering the looped conductor (1). A lead wire (5a) is connected to the conductor plate (2), and outputs from the lead wire (5a) and the lead wire (5b) are specified as a measurement output of an electromagnetic field probe.

### TECHNICAL FIELD

The present invention relates to an electromagnetic field probe that measures, in the vicinity of the equipment under test, the current flowing through equipment under test.

### BACKGROUND ART

A loop probe is generally used as a probe for measuring, in the vicinity of the equipment under test, the current flowing through equipment under test. The loop probe is disposed such that the magnetic flux generated from the equipment under test passes through the loop surface of the loop probe, and the induced current generated at that time is detected as the output voltage of the probe.

As such a probe, there has been conventionally one in which a loop probe is formed on a printed circuit board, and a GND pattern is attached around the loop wiring (coplanar structure). In this probe, it is assumed that the probe is disposed in parallel to the equipment under test, and the GND pattern is disposed around the antenna pattern (see, for example, Patent Literature 1).

### CITATION LIST

### Patent Literatures

Patent Literature 1: JP 2003-87044 A

### SUMMARY OF INVENTION

### Technical Problem

However, in the technology described in Patent Literature 1, the GND pattern is attached for the purpose of forming a coplanar structure covering the periphery of the antenna pattern, and the GND pattern does not exist at a central portion of the antenna pattern. Therefore, in the vicinity of the center of the antenna pattern, there is a problem that induced currents generated on each side of the antenna pattern cancel each other, and there is a region in which measurement cannot be performed.

The present invention has been made to solve such a problem, and it is an object of the present invention to provide an electromagnetic field probe capable of obtaining a stable output voltage regardless of the positions and directions of the equipment under test and the electromagnetic field probe.

### Solution to Problem

An electromagnetic field probe according to the present invention includes a looped conductor with both ends opened; and a conductor plate disposed parallel to a loop surface of the looped conductor and having a shape covering the looped conductor, in which one end of the both ends of the looped conductor is connected to the conductor plate, the other end is connected to a signal output terminal, and a potential difference between the signal output terminal and the conductor plate is specified as a measurement output.

### Advantageous Effects of Invention

In the electromagnetic field probe according to the present invention, the conductor plate is disposed in parallel to the loop surface of the looped conductor and having a size covering the looped conductor, and one end of both ends of the looped conductor is connected to the conductor plate, the other end is connected to a signal output terminal, and a potential difference between the signal output terminal and the conductor plate is specified as a measurement output. Thereby, a stable output voltage can be obtained regardless of the positions and directions of the equipment under test and the electromagnetic field probe.

### BRIEF DESCRIPTION OF DRAWINGS

FIG. 1 is a perspective view of an electromagnetic field probe according to a first embodiment of the present invention.

FIG. 2 is an exploded perspective view of the electromagnetic field probe according to the first embodiment of the present invention.

FIG. 3 is a side view of the electromagnetic field probe according to the first embodiment of the present invention.

FIG. 4 is a plan view of a looped conductor of the electromagnetic field probe according to the first embodiment of the present invention.

FIG. 5 is a side view showing the relationship between the electromagnetic field probe of the first embodiment of the present invention and a microstrip line to be measured.

FIG. 6 is a plan view showing an example of the looped conductor of the electromagnetic field probe according to the first embodiment of the present invention.

FIG. 7 is an explanatory diagram showing characteristics of the electromagnetic field probe according to the first embodiment of the present invention in comparison with the related art.

FIG. 8 is a perspective view of an electromagnetic field probe according to a second embodiment of the present invention.

FIG. 9 is an exploded perspective view of the electromagnetic field probe according to the second embodiment of the present invention.

FIG. 10 is a side view of the electromagnetic field probe according to the second embodiment of the present invention.

FIG. 11 is a plan view of a looped conductor of the electromagnetic field probe according to the second embodiment of the present invention.

FIG. 12 is an explanatory diagram of measurement conditions of the electromagnetic field probe according to the second embodiment of the present invention.

FIG. 13 is a side view at the time of measurement of the electromagnetic field probe according to the second embodiment of the present invention.

FIG. 14 is an explanatory diagram showing dimensions of the looped conductor of the electromagnetic field probe according to the second embodiment of the present invention.

FIG. 15 is an explanatory diagram showing measurement results of the electromagnetic field probe according to the second embodiment of the present invention.

FIG. 16 is an exploded perspective view of an electromagnetic field probe according to a third embodiment of the present invention.

FIG. 17 is a plan view of a looped conductor of the electromagnetic field probe according to the third embodiment of the present invention.

FIG. 18 is an explanatory diagram showing dimensions of the looped conductor of the electromagnetic field probe according to the third embodiment of the present invention.

FIG. 19 is a side view at the time of measurement of the electromagnetic field probe according to the third embodiment of the present invention.

FIG. 20 is an explanatory diagram showing a result of calculation using an electromagnetic field simulation of the electromagnetic field probe according to the third embodiment of the present invention.

FIG. 21 is an exploded perspective view of an electromagnetic field probe according to a fourth embodiment of the present invention.

FIG. 22 is a plan view showing a looped conductor of the electromagnetic field probe according to the fourth embodiment of the present invention.

FIG. 23 is a plan view showing another example of the looped conductor of the electromagnetic field probe according to the fourth embodiment of the present invention.

FIG. 24 is a plan view showing still another example of the looped conductor of the electromagnetic field probe according to the fourth embodiment of the present invention.

FIG. 25 is an exploded perspective view of an electromagnetic field probe according to a fifth embodiment of the present invention.

FIG. 26 is a side view of the electromagnetic field probe according to the fifth embodiment of the present invention.

FIGS. 27A and 27B are plan views showing looped conductors of the electromagnetic field probe according to the fifth embodiment of the present invention.

FIG. 28 is an exploded perspective view of a configuration at the time of measurement of the electromagnetic field probe according to the fifth embodiment of the present invention.

FIG. 29 is a side view of the configuration at the time of measurement of the electromagnetic field probe according to the fifth embodiment of the present invention.

FIGS. 30A, 30B and 30C are plan views showing the looped conductors of the electromagnetic field probe according to the fifth embodiment of the present invention.

FIG. 31 is an explanatory diagram showing measurement results of the electromagnetic field probe according to the fifth embodiment of the present invention.

### DESCRIPTION OF EMBODIMENTS

In order to explain this invention in more detail, a mode for carrying out the present invention will be described below with reference to the accompanying drawings.

### First Embodiment

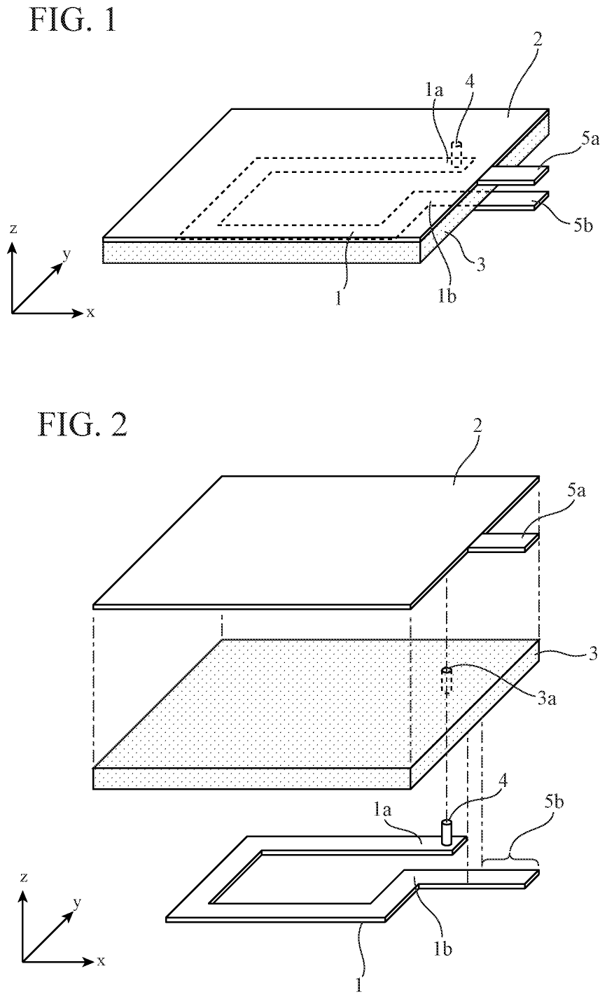

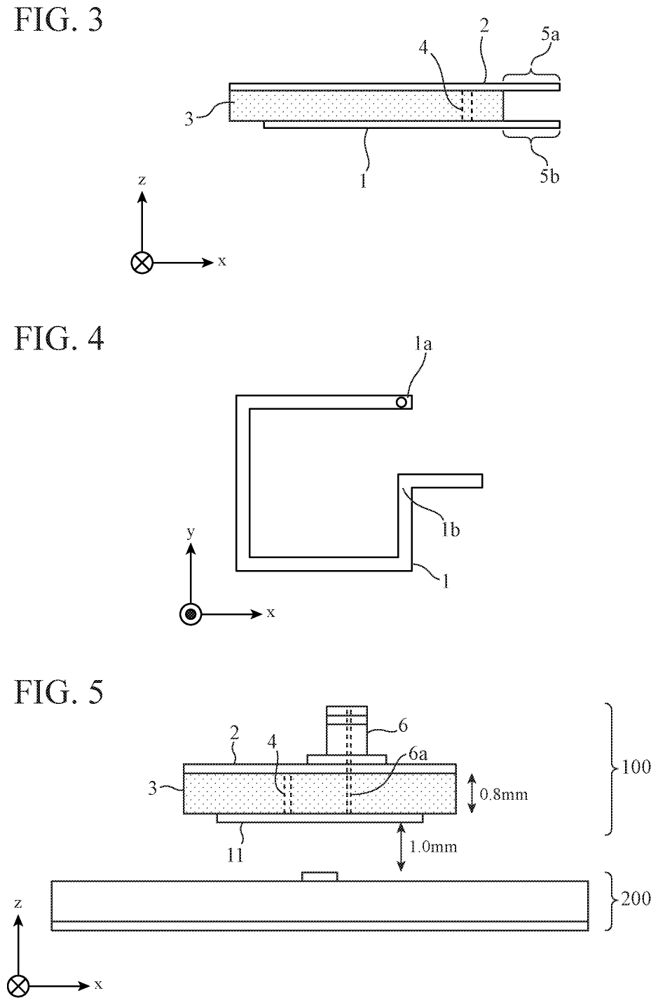

FIG. 1 is a perspective view showing a configuration of an electromagnetic field probe according to the present embodiment. FIG. 2 is an exploded perspective view of the electromagnetic field probe, FIG. 3 is a side view of the electromagnetic field probe, and FIG. 4 is a plan view showing a shape of a looped conductor. The electromagnetic field probe of the first embodiment will be described below with reference to these drawings.

The electromagnetic field probe according to the present embodiment is a two-layered printed circuit board in which a looped conductor 1 and a conductor plate 2 are disposed via a dielectric 3 as shown in these figures. The looped conductor 1 is a looped conductor whose both ends are opened, and is disposed on one surface of the printed circuit board. The conductor plate 2 is disposed on the other surface of the printed circuit board so as to be parallel to a loop surface of the looped conductor 1 and has a size that covers the looped conductor 1. One end 1a of the looped conductor 1 is connected to the conductor plate 2 by a via 4 through a through hole 3a provided in the dielectric 3. Further, the other end 1b of the looped conductor 1 is connected to a lead wire 5b for constituting a signal output terminal, and a potential difference with the lead wire 5a provided on the conductor plate 2 is specified as a measurement output from the electromagnetic field probe.

In this embodiment, although it is assumed that a coated wire or a coaxial cable is used as the lead wire 5a and the lead wire 5b, any wire can be used as long as it can connect between the electromagnetic field probe and the measuring instrument. Further, although it is assumed that an oscilloscope, a spectrum analyzer, or a network analyzer is used as the measuring instrument, any measuring instrument can be used as long as it can obtain an intended output.

The reason why this mode produces a desired effect will now be described. The reasons are the following two points, and the effects of the electromagnetic field probe in this embodiment can be produced by superimposing the respective effects.

1. By passing through the conductor plate 2 as a part of the electromagnetic field probe, an electric field produced by the equipment under test is received by each of the conductor plate 2 and the looped conductor 1 to generate a potential difference between the two, and thus an output voltage can be generated from the electromagnetic field probe even at a central portion of the loop.

2. Since an eddy current is generated by the conductor plate 2, it becomes difficult for the magnetic flux to pass through the loop surface of the looped conductor 1. In particular, since the induced current is suppressed at a position where the output voltage of the electromagnetic field probe is increased due to nearness of a line of the looped conductor 1 (one side of the conductor forming the loop in the case of a rectangular looped conductor) and a wiring to be measured, the output voltage can be reduced.

As described above, the output voltage (coupling amount) is increased at the central portion of the loop by the electric field component, and the magnetic field component at the point where the output voltage becomes large is suppressed, and thereby an output voltage with a small amount of fluctuation can be obtained from the electromagnetic field probe regardless of the positions (position characteristics and angular characteristics) of the equipment under test and the electromagnetic field probe. Note that although the shape of the looped conductor 1 is a quadrangle in FIGS. 1 to 4, it is not limited to this shape, and may be an oval or a polygon.

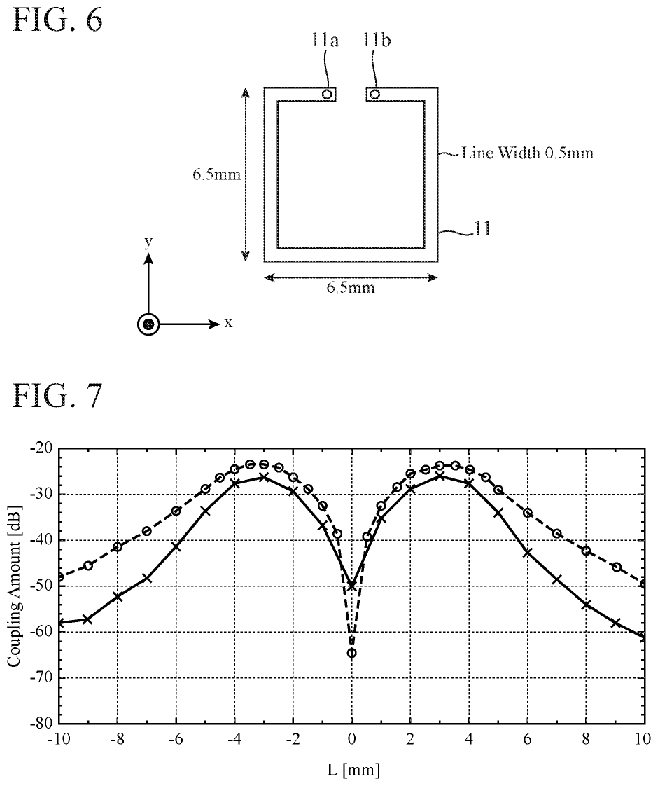

Next, the effects obtained by the electromagnetic field probe according to the present embodiment will be described with reference to FIGS. 5 to 7. FIG. 5 is a side view showing the relationship between an electromagnetic field probe and a microstrip line to be measured, FIG. 6 is a plan view showing an example of a looped conductor, and FIG. 7 is an explanatory diagram showing characteristics of the electromagnetic field probe according to the present embodiment in comparison with the related art.

As shown in FIG. 5, an electromagnetic field probe 100 is disposed at a predetermined distance from a microstrip line 200. In the illustrated example, the distance between these is set to 1.0 mm. Moreover, the thickness of the dielectric 3 is 0.8 mm. The electromagnetic field probe 100 connects one end 11a of a looped conductor 11 to the conductor plate 2 through the via 4. A coaxial connector 6 for connecting a coaxial cable is installed on the conductor plate 2, and connects the other end 11b of the looped conductor 11 to a core wire 6a of the coaxial connector 6. The coaxial connector 6 and the core wire 6a have a function as a signal output terminal from the looped conductor 11. That is, in the electromagnetic field probe 100 shown in FIG. 5, the signal output terminal is provided on the surface opposite to the looped conductor 11 with reference to the conductor plate 2. The looped conductor 11 uses a square looped conductor having a side of 6.5 mm square and is disposed with the dielectric 3 intervened between the conductor plate 2 having a side of 8.0 mm square and the looped conductor 11.

FIG. 7 shows the amount of coupling between the microstrip line 200 and the electromagnetic field probe 100 at 1 GHz when the electromagnetic field probe 100 is moved in the direction crossing the microstrip line 200. The solid line indicates the coupling amount of the electromagnetic field probe 100 of the first embodiment, and the broken line indicates the coupling amount of the conventional probe consisting only of loop-like probe elements. As shown in FIG. 7, it can be seen that at the position (L=0 mm) where the center line of the microstrip line 200 coincides with the center of the electromagnetic field probe 100, the coupling amount is larger than that of the conventional probe, which is more desirable than the conventional probe.

As a further effect of attaching the conductor plate 2, there is an improvement in ease of manufacture and ease of use. In the conventional loop probe without a conductor plate, since the connector itself becomes a part of the probe and disturbs the characteristics, it has been necessary to design in consideration of the shape of the connector and the mounting location. On the other hand, as in the case of the electromagnetic field probe 100 according to the first embodiment, the conductor plate 2 is provided between the microstrip line 200 to be measured and the coaxial connector 6 so that the influence of the electric field component and the magnetic field component coming out of the equipment under test on the coaxial connector 6 can be suppressed. As a result, the coaxial connector 6 can be attached to the electromagnetic field probe 100 regardless of the shape or the attachment position. Therefore, even when considering the shape of the connector, redesign is not necessary.

Moreover, when the coaxial connector 6 is used, since the conductor plate 2 and the outer conductor of the coaxial connector 6 can be surface-connected and they can be firmly fixed, the structure can be made resistant to breakage.

As described above, according to the electromagnetic field probe of the first embodiment, the electromagnetic field probe includes a looped conductor with both ends opened, and a conductor plate disposed parallel to a loop surface of the looped conductor and having a shape covering the looped conductor, in which one end of the both ends of the looped conductor is connected to the conductor plate, the other end is connected to a signal output terminal, and a potential difference between the signal output terminal and the conductor plate is specified as a measurement output, and therefore a stable output voltage can be obtained regardless of the positions and directions of the equipment under test and the electromagnetic field probe.

Further, according to the electromagnetic field probe of the first embodiment, the signal output terminal is provided on the side opposite to the looped conductor with reference to the conductor plate, and therefore the influence of the electric field component and the magnetic field component coming out of the equipment under test on the signal output terminal can be suppressed.

### Second Embodiment

In an electromagnetic field probe according to a second embodiment, one end or the other end of both ends of a looped conductor is positioned in a region inside a surface forming the loop. That is, when there is no looped conductor near the center of the electromagnetic field probe, it may be difficult for the looped conductor to catch the electric field component from the microstrip line. In the second embodiment, to resolve the problem, the looped conductor is positioned near the center of the electromagnetic field probe.

At both ends of the looped conductor, both the side not connected to the conductor plate and the side to be connected can be considered to be put inside the looped conductor, but in the following, an example in which the side not connected to the conductor plate is positioned inside will be described. Note that the same effect can be obtained by arranging so that the side to be connected to the conductor plate at the end of the looped conductor is positioned inside. Further, as in the first embodiment, the shape of the looped conductor may be circular or polygonal, but will be described as a quadrangle.

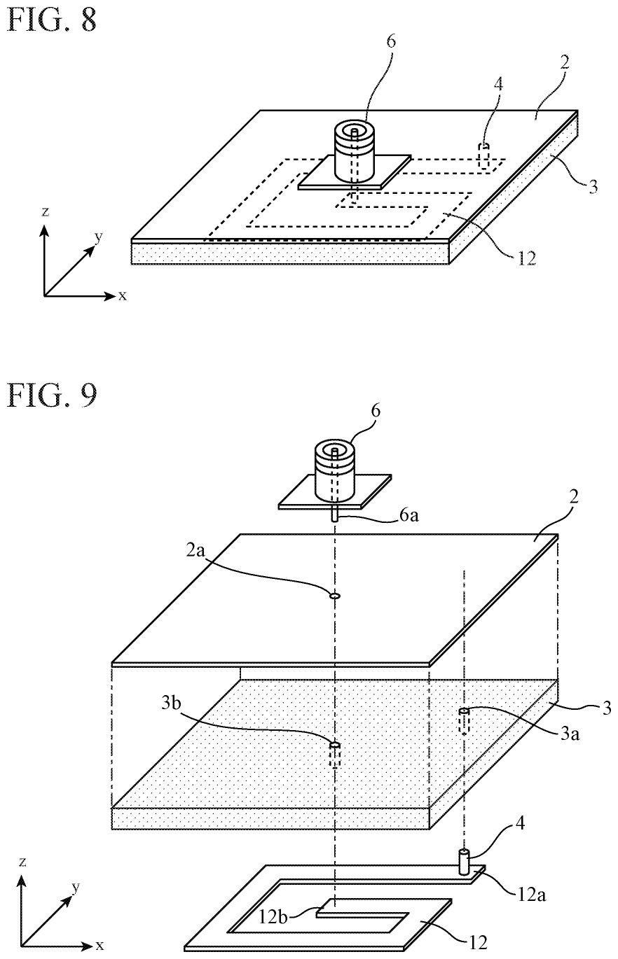

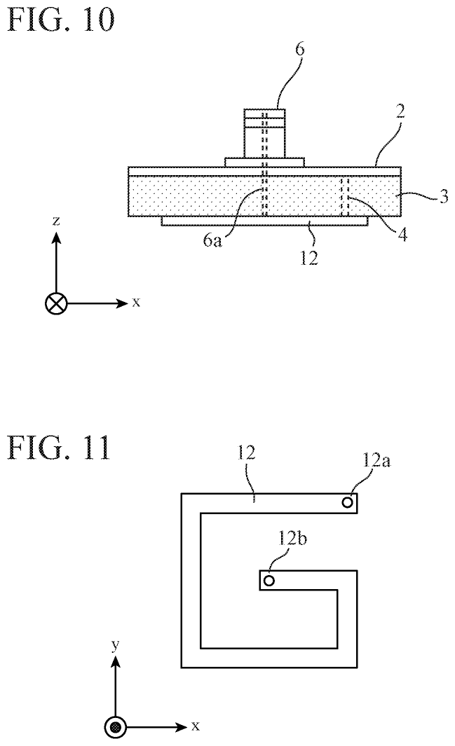

FIG. 8 is a perspective view showing the configuration of the electromagnetic field probe according to the present embodiment. FIG. 9 is an exploded perspective view of the electromagnetic field probe, FIG. 10 is a side view of the electromagnetic field probe, and FIG. 11 is a plan view showing the shape of the looped conductor. The electromagnetic field probe according to the second embodiment will be described below with reference to these drawings.

The electromagnetic field probe according to the present embodiment is constituted by a two-layer substrate as shown in these figures, and one end 12a of a looped conductor 12 is connected to the conductor plate 2 through the via 4 and the other end 12b extends in the inward direction from the middle portion of one side to near the central portion of the square region. That is, the other end 12b is configured to be positioned in the region inside the loop in the looped conductor 11. The other end 12b is connected to the core wire 6a of the coaxial connector 6 via a through hole 3b provided in the dielectric 3 and a clearance 2a provided in the conductor plate 2. In this example, the coaxial connector 6 is used, but as long as it can electrically connect from the electromagnetic field probe to the measuring instrument, any connector may be used as in the first embodiment. Note that when the coaxial connector 6 is used, the outer conductor of the coaxial connector 6 is connected to the conductor plate 2, and the core wire 6a is connected to the other end 12b of the looped conductor 11.

In the second embodiment, by arranging the end inside the loop of the looped conductor 12, a potential difference is easily generated between the looped conductor 12 and the conductor plate 2, and the signal can be easily detected even inside the loop.

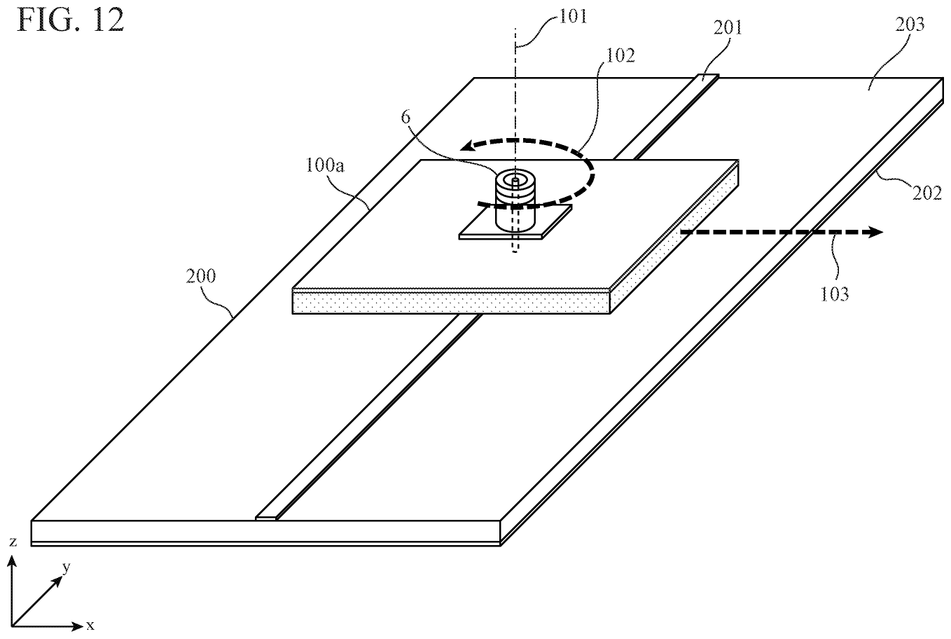

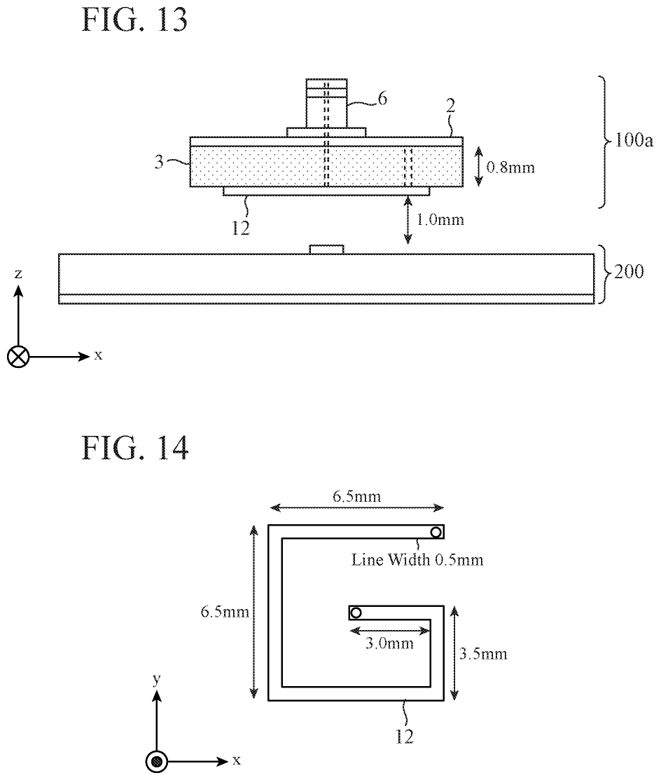

Under the conditions of the second embodiment, a probe having a terminal not connected to the conductor plate 2 placed inside the loop was manufactured using an FR-4 printed circuit board with a thickness of 0.8 mm. Then, the amount of coupling between the microstrip line and the electromagnetic field probe when the probe was moved in a direction crossing the microstrip line and rotated relative to the microstrip line was actually measured. FIG. 12 is an explanatory view of measurement conditions, FIG. 13 is a side view of FIG. 12, and FIG. 14 is an explanatory view showing dimensions of the looped conductor 12.

A spectrum analyzer (a tracking generator function of the spectrum analyzer injects −10 dBm into the microstrip line 200, and the 50Ω termination is connected to the end of the microstrip line 200 which is not connected to the tracking generator) was attached to the tip of an electromagnetic field probe 100a and measured. In the microstrip line 200, a signal line 201 and a ground conductor 202 are disposed via a dielectric 203. The electromagnetic field probe 100a rotates in a rotation direction 102 about a rotation axis 101 and moves in a movement direction 103.

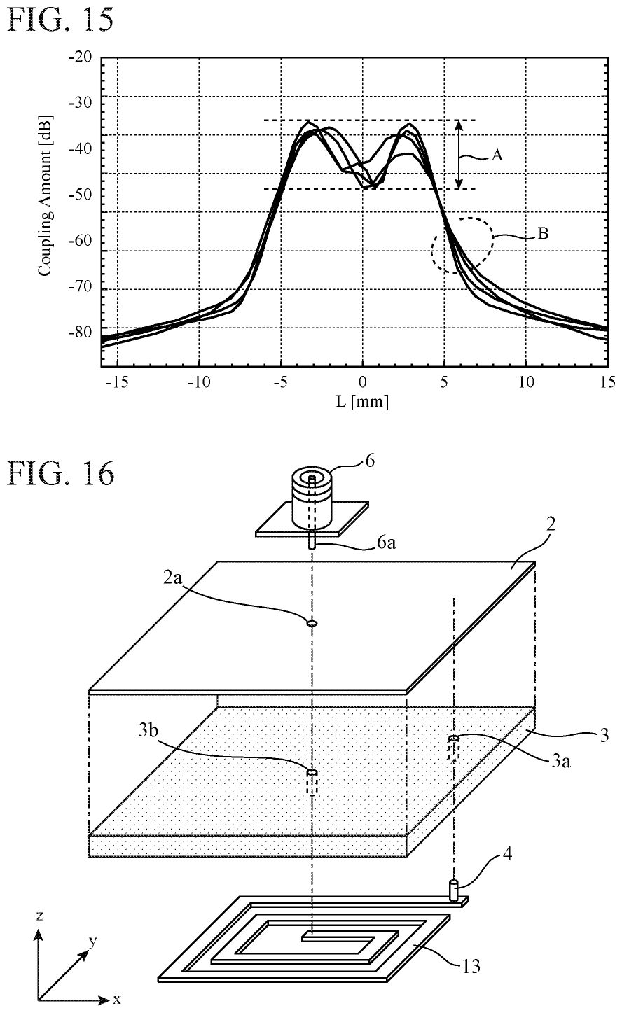

FIG. 15 shows the measurement results in the configuration shown in FIG. 12. In the figure, as shown in A, while the maximum value of the coupling amount is −28 dB, the minimum value of the coupling amount near the center of the electromagnetic field probe 100a is −37 dB, and the change of the coupling amount is about 10 dB, an improvement can be confirmed as compared with the conventional loop probe and the first embodiment. Further, a plurality of lines each show measurement results of different rotation angles when the electromagnetic field probe 100a is rotated, and it can be seen that the change in response to the angle is small as shown by B in the figure. In addition, it has been confirmed that similar results can be obtained also by electromagnetic field simulation.

As described above, according to the electromagnetic field probe of the second embodiment, since one end or the other end of the looped conductor is positioned in the region inside the surface forming the loop, a more stable output voltage can be obtained regardless of the positions and directions of the equipment under test and the electromagnetic field probe.

### Third Embodiment

In a third embodiment, the other end positioned inside the loop of the looped conductor is spiral.

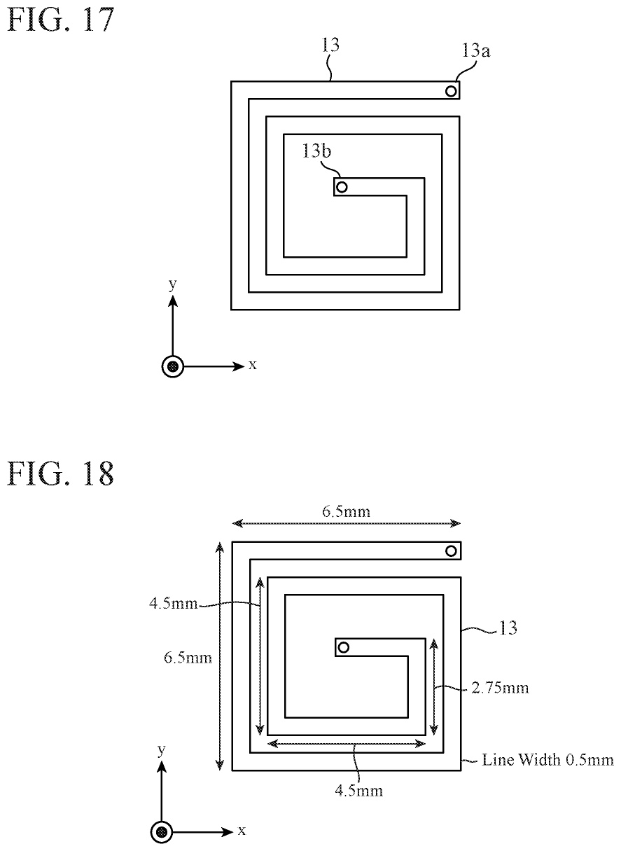

FIG. 16 is an exploded perspective view of the electromagnetic field probe according to the present embodiment, and FIG. 17 is a plan view showing the shape of the looped conductor. The electromagnetic field probe according to the third embodiment will be described below with reference to these drawings.

The basic configuration of the electromagnetic field probe of the third embodiment is the same as that of the second embodiment, but as shown in FIGS. 16 and 17, the other end 13b of a looped conductor 13 is spirally extended to near the center of a square region. The other end 13b is connected to the core wire 6a of the coaxial connector 6 via the through hole 3b provided in the dielectric 3 and the clearance 2a provided in the conductor plate 2 as in the second embodiment. Further, one end 13a of the looped conductor 13 is connected to the conductor plate 2 through the via 4 as in the first and second embodiments. Since the other configuration in FIG. 16 is the same as that of the second embodiment shown in FIG. 9, the corresponding portions are denoted by the same reference numerals and the description thereof will be omitted.

Forming the other end 13b side of the looped conductor 13 in a spiral shape makes it difficult to prevent the magnetic field component from penetrating the loop surface, and thus it is possible to favorably detect the electric field component while preventing the magnetic field component from being difficult to detect.

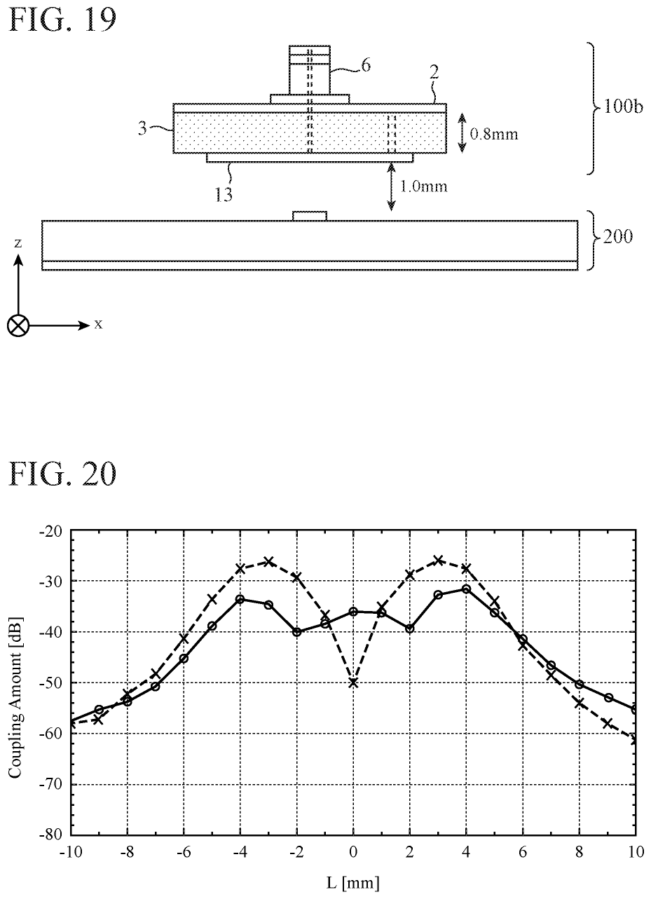

As an example for confirming this effect, FIG. 18 describes the dimensions of the looped conductor of the third embodiment. As shown, it has a structure in which a 4.5 mm square loop is contained in a 6.5 mm square loop. The line width is 0.5 mm. FIG. 19 shows the positional relationship with the microstrip line 200 when an electromagnetic field probe 100b is viewed from the side. The distance between the electromagnetic field probe 100b and the microstrip line 200 is 1.0 mm, and the thickness of the dielectric 3 in the electromagnetic field probe 100b is 0.8 mm. FIG. 20 shows the results calculated using electromagnetic field simulation under this condition. Compared to the first embodiment shown by the broken line, in the third embodiment shown by the solid line, although the maximum value of the coupling amount is smaller, it is understood that the decrease in the coupling amount at the center of the looped conductor 12 is suppressed.

As described above, according to the electromagnetic field probe of the third embodiment, one end or the other end of the looped conductor is spirally extended to the region inside the surface forming the loop, and thus a more stable output voltage can be obtained regardless of the positions and directions of the equipment under test and the electromagnetic field probe.

### Fourth Embodiment

The fourth embodiment is an example in which a conductor plate having a line width larger than the line width of the looped conductor is connected to one end or the other end of the looped conductor in a region inside the surface forming the loop. In the fourth embodiment, the end connecting the conductor plate is described as the other end, but the same effect can be obtained with one end.

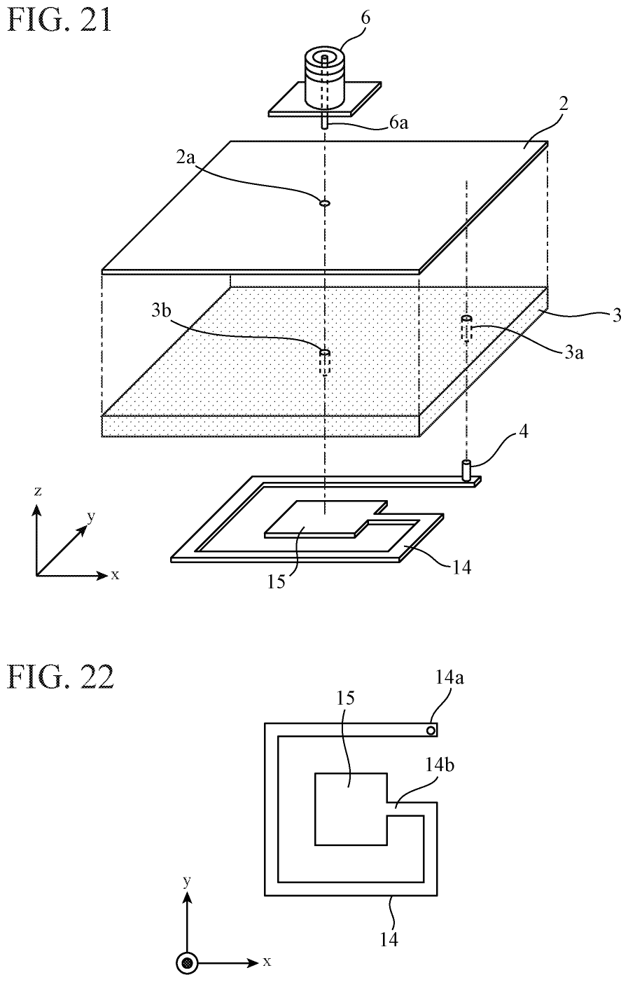

FIG. 21 is an exploded perspective view of the electromagnetic field probe according to the present embodiment, and FIG. 22 is a plan view showing the shape of the looped conductor. The electromagnetic field probe of the fourth embodiment will be described below with reference to these drawings.

In a looped conductor 14 of the present embodiment, a conductor plate 15 wider than the line width of the looped conductor 14 is connected to the other end 14b. The shape of the conductor plate 15 is not particularly limited as long as it has a portion wider than the line width of the looped conductor 14, but it is desirable to be symmetrical when the electromagnetic field probe is rotated relative to the equipment under test, and therefore a circular shape or a regular polygon is preferable and it is desirable to dispose it near the center of the loop of the looped conductor 14. The conductor plate 15 is connected to the core wire 6a of the coaxial connector 6 through the through hole 3b provided in the dielectric 3 and the clearance 2a provided in the conductor plate 2. Further, one end 14a of the looped conductor 14 is connected to the conductor plate 2 through the via 4 as in the first and second embodiments. Since the other configuration in FIG. 21 is the same as that of the second embodiment shown in FIG. 9, the corresponding portions are denoted with the same reference numerals, and the description thereof is omitted.

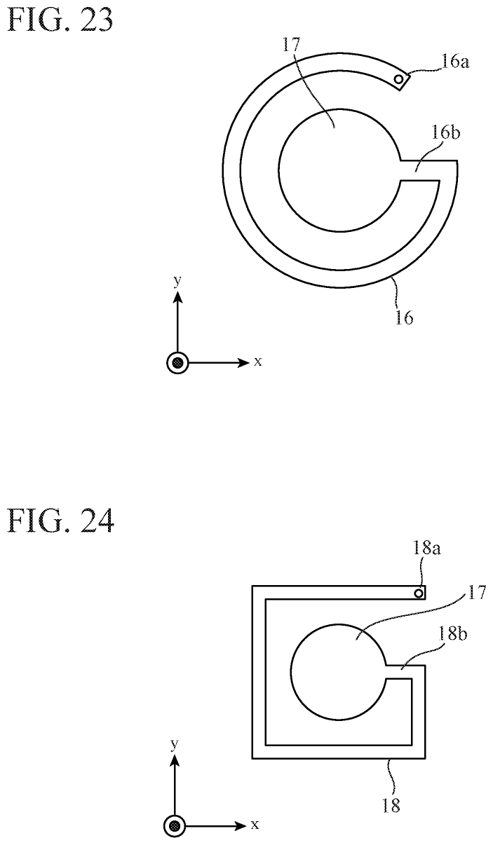

The example different from the looped conductor 14 of FIG. 21 and FIG. 22 is shown in FIG. 23 and FIG. 24. A looped conductor 16 of FIG. 23 is formed in a circular shape, and a circular conductor plate 17 is connected to the other end 16b. A looped conductor 18 of FIG. 24 is formed in a square shape, and a circular conductor plate 17 is connected to the other end 18b. Note that each of the one ends 16a and 18a is connected to the conductor plate 2 through the via 4 and the conductor plate 17 is connected to the core wire 6a of the coaxial connector 6, as with the looped conductor 14 shown in FIG. 22. As shown in FIGS. 23 and 24, the shape of the conductor plate 17 may or may not be matched with the looped conductor 16 (18).

As described above, in the fourth embodiment, the conductor plates 15 and 17 can make it easy to receive the electric field component in a region where the received voltage near the center of the loop tends to be weak. The reason why the electric field component can be easily received is that as a result of an increase in the area of the electromagnetic field probe facing the signal line of the microstrip line to be measured, the electric field component can be easily detected by the electrostatic capacitance. On the other hand, although the conductor plate 2 also receives the electric field component, since the distance from the microstrip line is long, and the conductor plates 15 and 17 and the looped conductors 14, 16, 18 are intervened between the microstrip line and the conductor plate 2, it is difficult to be affected by the electric field from the microstrip line, and a potential difference is easily generated between the conductor plate 2 and the conductor plates 15, 17. As a result, the received voltage at the central portion of the loop can be increased.

As described above, according to the electromagnetic field probe of the fourth embodiment, since one end or the other end of the looped conductor is configured to be connected to the conductor plate having a line width larger than the line width of the looped conductor in a region inside the surface forming the loop, a more stable output voltage can be obtained regardless of the positions and directions of the equipment under test and the electromagnetic field probe.

### Fifth Embodiment

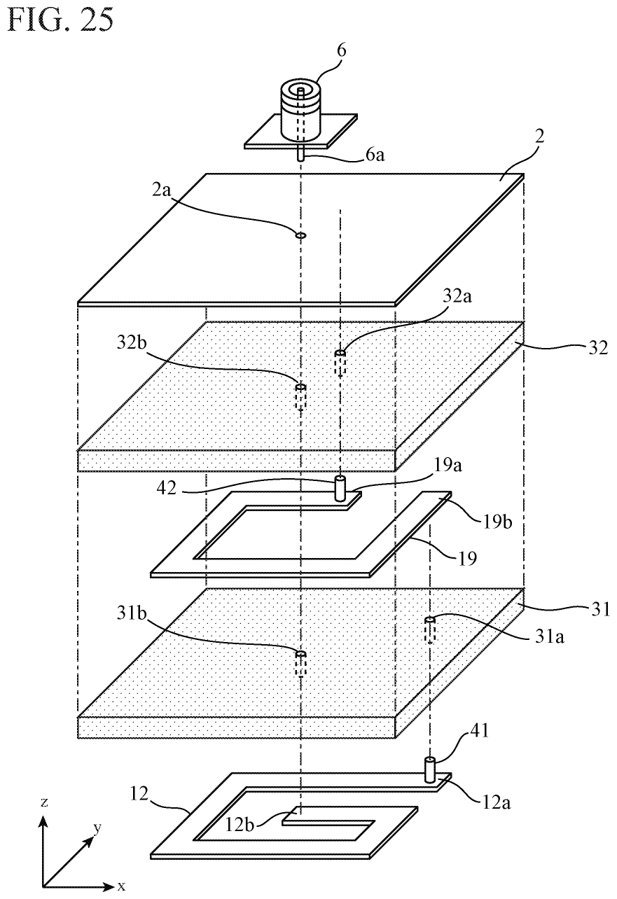

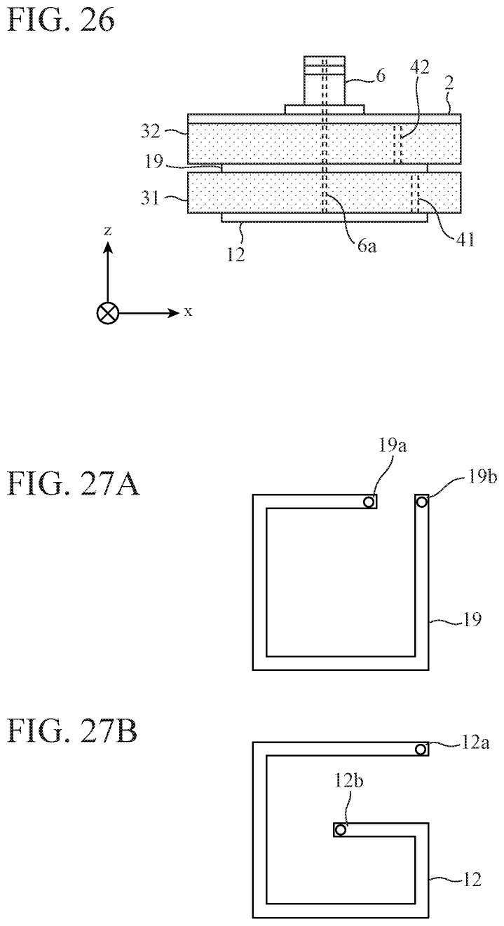

In a fifth embodiment, a plurality of looped conductors are provided, and the plurality of looped conductors are connected to form one continuous looped conductor. FIG. 25 is an exploded perspective view of an electromagnetic field probe according to the fifth embodiment, FIG. 26 is a side view of the electromagnetic field probe, and FIGS. 27A and 27B are plan views showing the shape of a looped conductor. The electromagnetic field probe of the fifth embodiment will be described below with reference to these drawings.

The electromagnetic field probe according to the fifth embodiment is constituted by a three-layer substrate as shown in these figures, and the looped conductor 12 of the first layer and the looped conductor 19 of the second layer are provided with a dielectric 31 intervened therebetween, and the looped conductor 19 of the second layer and the conductor plate 2 are provided with a dielectric 32 intervened therebetween. Here, the looped conductor 12 is the same as the looped conductor 12 of the second embodiment. The looped conductor 19 is a square looped conductor, and the end of one side is the other end 19b, and the end of one side close to the other end 19b is the one end 19a.

One end 12a of the looped conductor 12 is connected to the other end 19b of the looped conductor 19 through a via 41 in a through hole 31a provided in the dielectric 31. Further, the core wire 6a of the coaxial connector 6 is connected to the other end 12b of the looped conductor 12 through the through hole 31b provided in the dielectric 31, the through hole 32b provided in the dielectric 32, and the clearance 2a provided in the conductor plate 2. Furthermore, one end 19a of the looped conductor 19 is connected to the conductor plate 2 through the via 42 in the through hole 32a provided in the dielectric 32. Thus, the looped conductor 12 and the looped conductor 19 are connected to the conductor plate 2 and the coaxial connector 6 as one continuous looped conductor. Note that although the outer dimensions of the looped conductors 12 and 19 are the same in these drawings, they are not particularly limited to the same dimensions.

In general, in the loop probe, the strength of the output voltage changes with the amount of magnetic flux penetrating the loop surface, and the larger the amount of magnetic flux penetrating, the larger the voltage can be output. Since the electromagnetic field probe of the present invention also has a feature as a loop probe, the output voltage can be increased by increasing the number of turns.

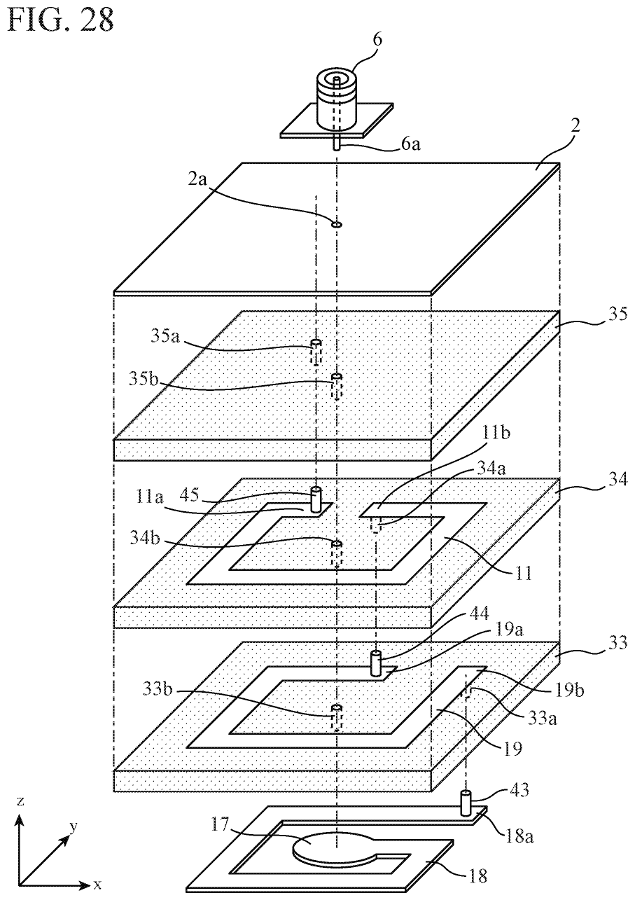

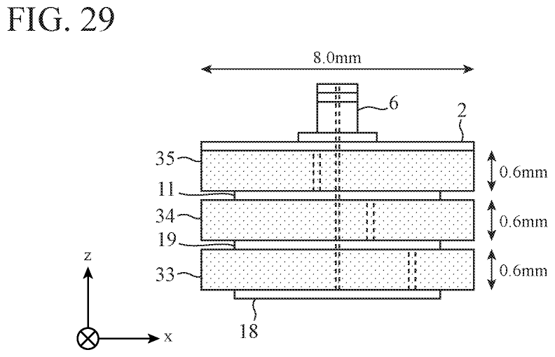

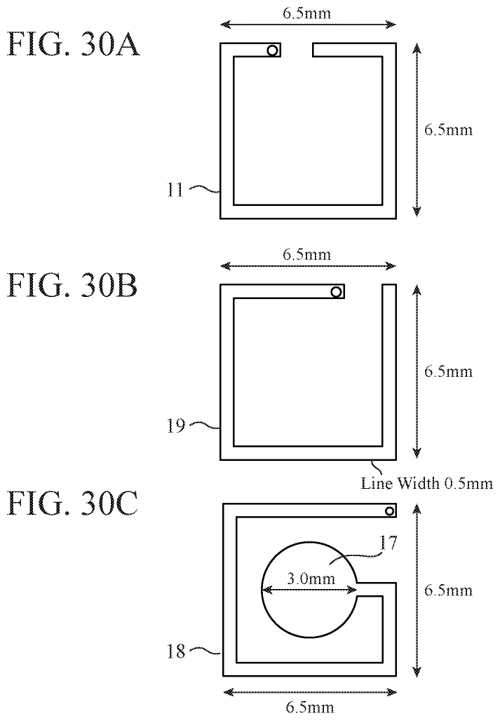

In order to confirm the effect of the fifth embodiment, a prototype was made. FIG. 28 is an exploded perspective view of a prototype electromagnetic field probe, FIG. 29 is a side view of the electromagnetic field probe, and FIGS. 30A, 30B, and 30C are plan views showing the shape of a looped conductor. The electromagnetic field probe shown in these figures is made of a four-layer substrate, one of the four layers is provided with the conductor plate 2, and the remaining three layers are provided with the looped conductors 18, 19, 11. Of the looped conductors 18, 19, 11, the looped conductor 18 of the first layer is the same as the looped conductor 18 shown in FIG. 24 of the fourth embodiment, as shown in FIG. 30C. As shown in FIG. 30B, the looped conductor 19 of the second layer is similar to the looped conductor 19 shown in FIGS. 25 to 27A. The looped conductor 11 of the third layer is the same as the looped conductor 11 shown in FIGS. 5 and 6 of the first embodiment, as shown in FIG. 30A.

The thickness of each of the dielectrics 33, 34, 35 is 0.6 mm, and the conductor plate 2 is 8 mm square. In addition, the looped conductors 18, 19, 11 each have a line width of 0.5 mm and a square of 6.5 mm on a side, and the conductor plate 17 has a circular shape with a diameter of 3 mm. One end 18a of the looped conductor 18 is connected to the other end 19b of the looped conductor 19 through a via 43 in a through hole 33a provided in the dielectric 33. One end 19a of the looped conductor 19 is connected to the other end 11b of the looped conductor 11 through a via 44 in a through hole 34a provided in the dielectric 34. One end 11a of the looped conductor 11 is connected to the conductor plate 2 through a via 45 in a through hole 35a provided in the dielectric 35. The core wire 6a of the coaxial connector 6 is connected to the conductor plate 17 of the looped conductor 18 through the clearance 2a of the conductor plate 2 and the through holes 35b, 34b and 33b.

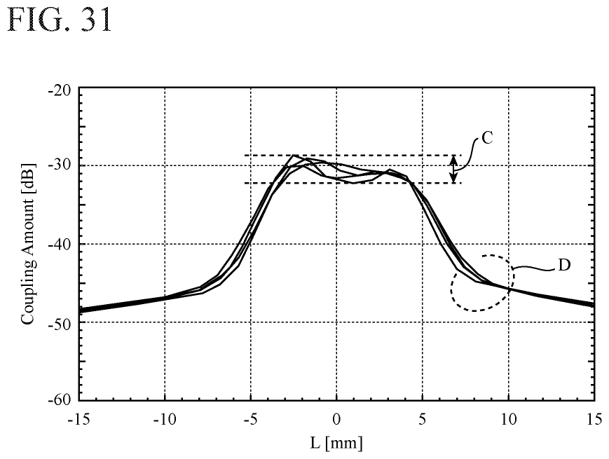

FIG. 31 shows the amount of coupling between the microstrip line and the electromagnetic field probe at 1 GHz when the electromagnetic field probe is moved in the direction crossing the microstrip line using the electromagnetic field probe shown in FIGS. 28 to 30.

As shown by C in the figure, it is understood that the drop at the center of the electromagnetic field probe is as small as about 2 dB, which is an ideal characteristic. Further, as shown in D, the effect that the change in response to the angle can be reduced is the same as in the first to fourth embodiments. With regard to the value of the output (coupling amount), the addition of the conductor plate 17 hinders the magnetic flux passing through the loop, and thus acts in the direction of reducing the value at the end of the probe (L=±4 mm) where the coupling amount is maximum, compared to the case where the conductor plate 17 is absent. On the other hand, since the coupling amount can be increased by increasing the number of turns, the maximum value of the coupling amount is not changed even if the conductor plate 17 is added, and only the coupling amount at the central portion of the loop can be further increased by the effect of the conductor plate 17.

As described above, according to the electromagnetic field probe of the fifth embodiment, a plurality of the looped conductors are each provided in different layers, one end of each of the looped conductors is connected to the other end of the looped conductor of another layer and the other end is connected to one end of the looped conductor of another layer to convert the plurality of looped conductors into one continuous looped conductor, and one end of the looped conductor not connected to another looped conductor is connected to the conductor plate and the other end of the looped conductor not connected to another looped conductor is specified as the signal output terminal, and therefore a more stable output voltage can be obtained regardless of the positions and directions of the equipment under test and the electromagnetic field probe.

It should be noted that the invention of the present application can freely combine the respective embodiments, modify an arbitrary constituent element of each embodiment, or omit an arbitrary constituent element in each embodiment within the scope of the invention.

### INDUSTRIAL APPLICABILITY

As described above, the electromagnetic field probe according to the present invention relates to the configuration of a loop probe that measures, in the vicinity of the equipment under test, the current flowing through the equipment under test, and is suitable for detecting the current generated on the printed circuit board wiring.

### REFERENCE SIGNS LIST

1, 11, 12, 13, 14, 16, 18, 19: looped conductor, 1a, 11a, 12a, 13a, 14a, 16a, 18a, 19a: one end, 1b, 11b, 12b, 13b, 14b, 16b, 18b, 19b: the other end, 2, 15, 17: conductor plate, 2a: clearance, 3, 31, 32, 33, 34, 35: dielectric, 3a, 3b, 31a, 31b, 32a, 32b, 33a, 33b, 34a, 34b, 35a, 35b: through hole, 4, 7, 41, 42, 43, 44, 45: via, 5a, 5b: lead wire, 6: coaxial connector, 6a: core wire, 100, 100a, 100b: electromagnetic field probe, 101: axis of rotation, 102: rotation direction, 103: movement direction, 200: microstrip line, 201: signal line, 202: ground conductor, 203: dielectric.

1. An electromagnetic field probe comprising:
a looped conductor with both ends opened; and
one conductor plate disposed parallel to a loop surface of the looped conductor and only on one side of the loop surface, and having a shape covering the looped conductor and a region inside the looped conductor, wherein
one end of the both ends of the looped conductor is connected to the conductor plate, another end is connected to a signal output terminal, and a potential difference between the signal output terminal and the conductor plate is specified as a measurement output.

2. The electromagnetic field probe according to claim 1, wherein the signal output terminal is provided on an opposite side to the looped conductor with reference to the conductor plate.

3. The electromagnetic field probe according to claim 1, wherein one end or the other end of the looped conductor is positioned in a region inside a surface forming a loop.

4. The electromagnetic field probe according to claim 3, wherein one end or the other end of the looped conductor is spirally extended to the region inside the surface forming the loop.

5. The electromagnetic field probe according to claim 3, wherein one end or the other end of the looped conductor is connected to a conductor plate having a line width larger than a line width of the looped conductor in the region inside the surface forming the loop.

6. The electromagnetic field probe according to claim 1, wherein a plurality of the looped conductors are each provided in different layers, one end of each of the looped conductors is connected to the other end of the looped conductor of another layer and the other end is connected to one end of the looped conductor of another layer to convert the plurality of looped conductors into one continuous looped conductor, and one end of the looped conductor not connected to another looped conductor is connected to the conductor plate and the other end of the looped conductor not connected to another looped conductor is specified as the signal output terminal.
